(19) United States
(12) Patent Application Publication
(10) Pub. No.: US 2018/0366852 A1
(43) Pub. Date: Dec. 20, 2018

(54) CONNECTING CABLE ASSEMBLY, ELECTRICAL CONNECTOR ASSEMBLY AND PADDLE CARD THEREOF

(71) Applicant: CviLux Corporation, New Taipei City (TW)

(72) Inventor: CHAO-CHUN YANG, Taipei City (TW)

(21) Appl. No.: 15/926,298

(22) Filed: Mar. 20, 2018

(30) Foreign Application Priority Data
Jun. 14, 2017 (TW) 106208601
Jun. 14, 2017 (TW) 106208602
Jun. 14, 2017 (TW) 106208603

(51) Int. Cl. H01R 12/77; H01R 12/53; H01R 12/72; H01R 13/6592; H05K 3/34; H05K 1/11

(52) U.S. Cl. CPC H01R 12/775; H01R 12/53; H01R 12/721; H05K 2201/09372; H05K 3/3405; H05K 1/111; H01R 13/6592

(57) ABSTRACT

An electrical connector assembly includes an electrical connector and a paddle card. The electrical connector has a terminal assembly, and the paddle card has a main body, a plurality of contacting pads, and a grounding strip pad. The main body has a first surface, a second surface, a front edge, and a rear edge; a plurality of contacting pads disposed on the main body. The contacting pads are correspondingly connected to the terminal assembly. A plurality of first-group soldering pads are disposed on the first surface. A plurality of second-group soldering pads are disposed on the second surface. A pair of positioning concaved-portions are respectively disposed at two sides of the paddle card closed to the rear edge. The grounding strip pad is formed on the paddle card in a traverse manner, and has two ends extending to the pair of positioning concaved-portions.

### BACKGROUND OF THE INVENTION

### 1. Field of the Invention

The present disclosure is related to a connecting cable assembly, an electrical connector assembly and a paddle card thereof. In particular, the present disclosure relates to an electrical connector assembly for transmitting data at high speed, and has an electrical connector and a paddle card being able to connect the electrical connector with a cable.

### 2. Description of Related Art

Cables are needed for electronic devices or electronic products to connect with each other for signal transmission. Because of the development of electronic technology, the speed of signal transmission is required faster and faster. The two ends of the cable usually have an electrical connector, respectively, to be inserted into the electronic devices or the electronic products. To conveniently connect the electrical connectors to the cable therebetween, a transmitting circuit board, which is also called a paddle card, is usually provided. The structure of the cable usually is constructed to form an impendence profile, and includes a shielding metallic braided layer. Wires of the cable are spread and arranged to solder with contacting pads, which are formed on a rear end of the paddle card. After the shielding metallic braided layer between the paddle card and the wires of the cable is removed, interference during high-speed signal transmission is likely to occur. Thus, the abovementioned drawbacks of the interference leave room for improvement in the art. In addition, the number of terminals of the electrical connector is increasing, thus a better design is proposed to easily and stably for assembling the paddle card.

### SUMMARY OF THE INVENTION

One of the objectives of the present disclosure is to provide an electrical connector assembly and a paddle card thereof to solve the abovementioned problems.

In order to achieve the above objectives, according to one exemplary embodiment of the present disclosure, an electrical connector assembly includes an electrical connector and a paddle card is provided. The electrical connector has a terminal assembly configured as a plurality of first terminals and a plurality of second terminals. The terminal assembly is extended to a rear end of the electrical connector. The paddle card has a main body, a plurality of contacting pads, a plurality of first-group soldering pads, a plurality of second-group soldering pads and a grounding strip pad. The main body has a first surface, a second surface, a front edge, and a rear edge. The second surface and the first surface are opposite. The contacting pads are disposed on the main body and close to the front edge. The contacting pads are correspondingly connected to the terminal assembly. The first-group soldering pads are disposed on the first surface. The second-group soldering pads are disposed on the second surface. A pair of positioning concaved-portions is respectively formed at two sides of the paddle card and close to the rear edge. The grounding strip pad is formed across the paddle card. The grounding strip pad has two ends respectively extending to a surface of the pair of the positioning concaved-portions.

In order to achieve the above objectives, the present disclosure also provides a paddle card. The paddle card includes a main body, a plurality of contacting pads, a plurality of first-group soldering pads, a plurality of second-group soldering pads and a grounding strip pad. The main body has a first surface, a second surface, a front edge, and a rear edge. The second surface and the first surface are opposite. The contacting pads are disposed on the main body and close to the front edge. The first-group soldering pads are disposed on the first surface. The second-group soldering pads are disposed on the second surface. A pair of positioning concaved-portions is respectively formed on two sides of the paddle card and close to the rear edge. The grounding strip pad is formed across the paddle card. The grounding strip pad having two ends respectively extended to surfaces of the pair of positioning concaved-portions.

Another one of the objectives of the present disclosure is to provide a connecting cable assembly, which can save time of wire routing of the connecting cable assembly.

In order to achieve the above objectives, according to one exemplary embodiment of the present disclosure, a connecting cable assembly is provided, which includes a pair of electrical connectors, a first paddle card, a second paddle card, and a cable. The pair of electrical connectors respectively has a terminal assembly. The first paddle card is soldered to one of the pair of electrical connectors. The first paddle card has a first surface, and a second surface. The first paddle card has a plurality of first-group soldering pads, and a plurality of second-group soldering pads. The first-group soldering pads are disposed on the first surface of the first paddle card. The second-group soldering pads are disposed on the second surface of the first paddle card. The second paddle card is soldered to the other of the pair of electrical connectors. The second paddle card has a first surface, and a second surface. The second paddle card has a plurality of first-group soldering pads, and a plurality of second-group soldering pads. The first-group soldering pads are disposed on the first surface of the second paddle card. The second-group soldering pads are disposed on the second surface of the second paddle card. The cable has a first wire group and a second wire group. The first wire group has two ends respectively soldered to the first-group soldering pads of the first paddle card and the first-group soldering pads of the second paddle card. The second wire group has two ends respectively soldered to the second-group soldering pads of the first paddle card and the second-group soldering pads of the second paddle card. Pin positions and functions of the first-group soldering pads of the first paddle card are symmetrical to pin positions and functions of the first-group soldering pads of the second paddle card. Pin positions and functions of the second-group soldering pads of the first paddle card are symmetrical to pin positions and functions of the second-group soldering pads of the second paddle card.

Thus, the present disclosure has advantages as follows. The electrical connector assembly and the paddle card can help the electrical connector assembly to be stably assembled with the paddle card, and the design of the paddle card helps the electrical connector assembly for conveniently and accurately achieves grounding and shielding. The connecting cable assembly is able to arrange the wires of the cable according to color and pin functions, to distribute in order as the first wire group and the second wire group. Since there is symmetrical and mapping relationship, it can save time for wire routing.

For further understanding of the present disclosure, reference is made to the following detailed description illustrating the embodiments and examples of the present disclosure. The description is for illustrative purpose only and is not intended to limit the scope of the claim.

### BRIEF DESCRIPTION OF THE DRAWINGS

FIG. 1 is a perspective view of an electrical connector assembly and a paddle card of the present disclosure;

FIG. 2 is an assembled perspective view of the electrical connector assembly connected to a cable to form a connecting cable assembly of the present disclosure;

FIG. 3 is a top view of the connecting cable assembly of the present disclosure;

FIG. 4 is a bottom view of the connecting cable assembly of the present disclosure;

FIG. 5 is a top view of the connecting cable assembly of the present disclosure;

FIG. 6 is a bottom view of the connecting cable assembly of the present disclosure;

FIG. 7 is a side view of the connecting cable assembly of the present disclosure;

FIG. 8 is a top view of the paddle card of another embodiment of the present disclosure;

FIG. 9 is a bottom view of the paddle card of the present disclosure;

FIG. 10 is top view of the electrical connector of the present disclosure;

FIG. 11 is a partial cross-sectional view of the electrical connector of the present disclosure;

FIG. 12 is a perspective view of the terminal assembly of the present disclosure;

FIG. 13 is a top view of the electrical connector soldered on a circuit board of the present disclosure; and

FIG. 14 is a partial cross-sectional view of the electrical connector soldered on the circuit board of the present disclosure.

### DETAILED DESCRIPTION OF THE EXEMPLARY EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings.

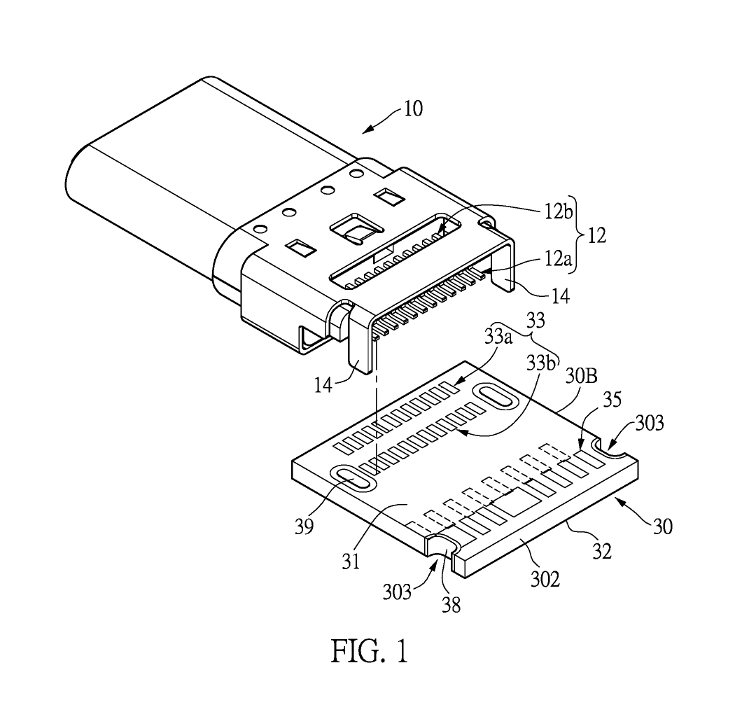

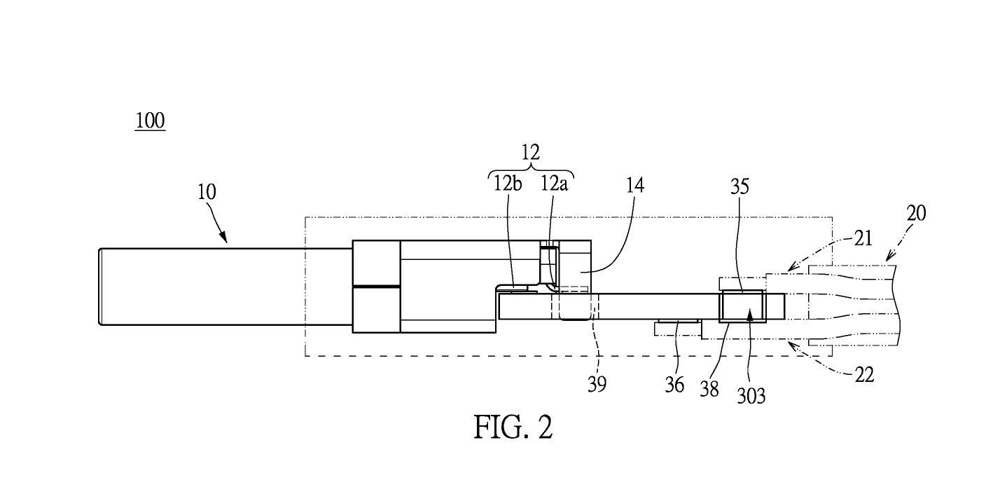

Reference is made to FIG. 1, which is a three-dimensional view of an electrical connector assembly and a paddle card of the present disclosure. The electrical connector assembly includes an electrical connector 10 and a paddle card 30. As shown in FIG. 2, the electrical connector assembly can connect with a cable 20 to form a connecting cable assembly 100. The cable 20 has a plurality of wires (21, 22). The wires can be configured as a first wire group 21 and a second wire group 22.

The electrical connector 10 has a terminal assembly 12 which is configured as a plurality of first terminals 12a and second terminals 12b. The terminal assembly 12 is extended to a rear end of the electrical connector 10. The electrical connector 10 in this embodiment is illustrated with a TYPE-C USB as an example, but it is not limited thereto.

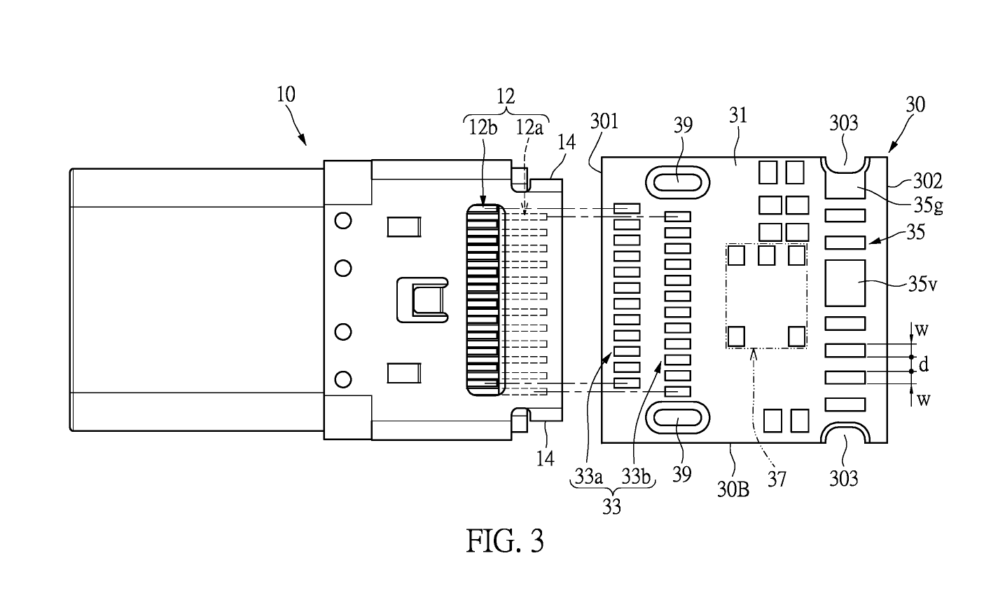

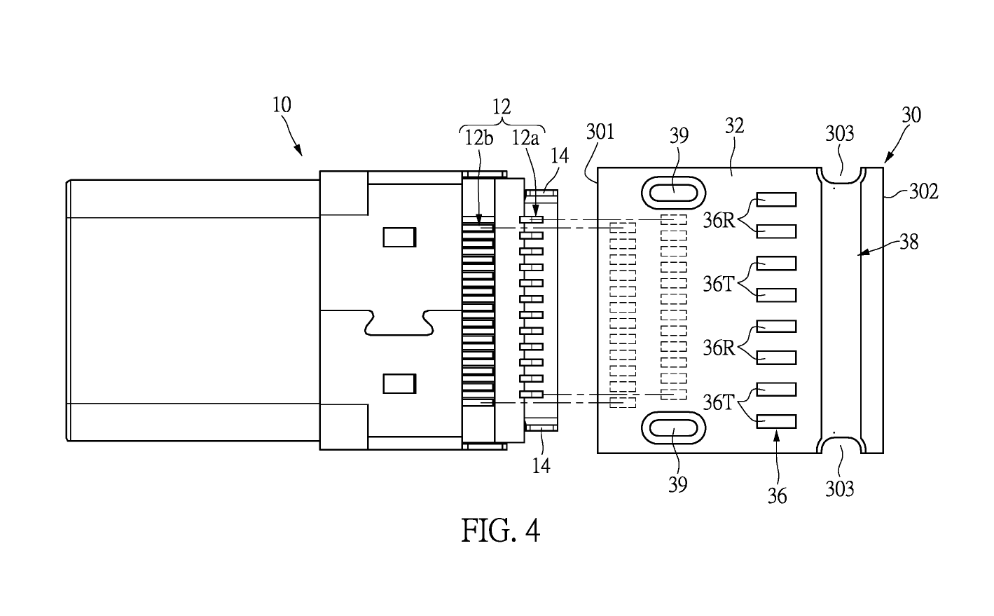

Reference is made to FIG. 3 and FIG. 4, which are a top view and a bottom view of the electrical connector assembly of the present disclosure. The paddle card 30 is disposed between the electrical connector 10 and the cable 30. The paddle card 30 has a main body 30B. The main body 30B has a first surface 31, a second surface 32 opposite to the first surface 31, a front edge 301 close to the electrical connector 10, and a rear edge 302 close to the cable 20. The paddle card 30 has a plurality of contacting pads 33, a plurality of first-group soldering pads 35 formed on the first surface 31, a plurality of second-group soldering pads 36 formed on the second surface 32, a pair of positioning concaved-portions 303 and a grounding strip pad 38. The contacting pads 33 are close to the front edge 301. The contacting pads 33 are electrically connected to the first-group soldering pads 35 and the second-group soldering pads 36, respectively. The pair of positioning concaved-portions 303 are respectively formed at two sides of the paddle card 30 and closed to the rear edge 302. The grounding strip pad 38 (ground bar) is formed across the paddle card 30. Two ends of the grounding strip pad 38 are respectively extended to the surface of the pair of positioning concaved-portion 303.

The first wire group 21 of the cable 20 is correspondingly connected to the first-group soldering pads 35. The second wire group 22 of the cable 20 is correspondingly connected to the second-group soldering pads 36. The terminal assembly 12 is correspondingly connected to the contacting pads 33.

One characteristic of this embodiment is that, the electrical connector 10 adapts SMT Surface-mount technology. Ends of the first terminal 12a and end of the second terminals 12b are arranged in the same plane, that is, coplanar. The contacting pads 33 are formed on the first surface 31 of the paddle card 30. Comparing with the splint soldering manner, this embodiment is beneficial to increase the yield rate and improve the productivity.

In this embodiment, the contacting pads 33 are configured as a first-row contacting pads 33a and a second-row contacting pads 33a. Pins of the first terminal 12a are correspondingly connected to the first-row contacting pads 33a. Pins of the second terminal 12b are correspondingly connected to the second-row contacting pads 33b. The first-row contacting pads 33a and the second-row contacting pads 33b are staggered to each other, not aligned. In this embodiment, the pins of the terminal assembly 12 are arranged in two rows and staggered, which are beneficial to check the soldering condition of terminals.

The paddle card 30 further has a pair of position holes 39. The electrical connector 10 has a pair of fixing legs 14. The pair of fixing legs 14 is correspondingly inserted into the pair of position holes 39. The position holes 39 are respectively disposed at two sides of the second-row contacting pads 33b. The fixing legs 14 can make the electrical connector 10 to be stably fixed to the paddle card 30.

Another characteristic of this embodiment is that the grounding strip pad 38 is formed across the second surface 32 of the paddle card 30 in a direction parallel to the rear edge 302. In addition, two ends of the grounding strip pad 38 respectively extend to the surface of the pair of positioning concaved-portions 303, and partially extend to the first surface 31 of the paddle card 30. In this embodiment, the positioning concaved-portion 303 is U-shaped, and is concaved from a side edge of the paddle card 30. A width of the grounding strip pad 38 is substantially equal to a maximum width of the positioning concaved-portion 303. The grounding strip pad 38 of this embodiment is not only convenient for the wires of the cable 20 being grounded, but also capable of connecting to a shielding element (not shown) on a periphery of the cable 20 for providing a shielding function. The positioning concaved-portion 303 can be used to receive a hot bar for positioning the paddle card 30. The paddle card 30 of this embodiment can be applied in automatic soldering compatibly with a flat-type or round-type cable 20.

A supplementary noted is that, the first-group soldering pads 35 are formed on the first surface 31 of the paddle card 30, and arranged between the pair of positioning concaved-portions 303. The second-group soldering pads 36 are formed on the second surface 32 of the paddle card 30. The first-group soldering pads 35 include a ground soldering pad 35g. The ground soldering pad 35g is close to one of the positioning concaved-portions 303 and is connected to the grounding strip pad 38. As shown in FIG. 3, the pin functions of the electrical connector 10 of this embodiment are exemplified as a USB 3.1 Type-C specification. Pin names of the other first-group soldering pads 35 from top to bottom in order are Ground (ground soldering pad 35g), Vconn (Power), CC (Configuration Channel), Vcc, Vcc (plug configuration detection), SBU2 (Side Band Use), D+, D− (Differential signal pair of USB 2.0), and SBU1 (Side Band Use).

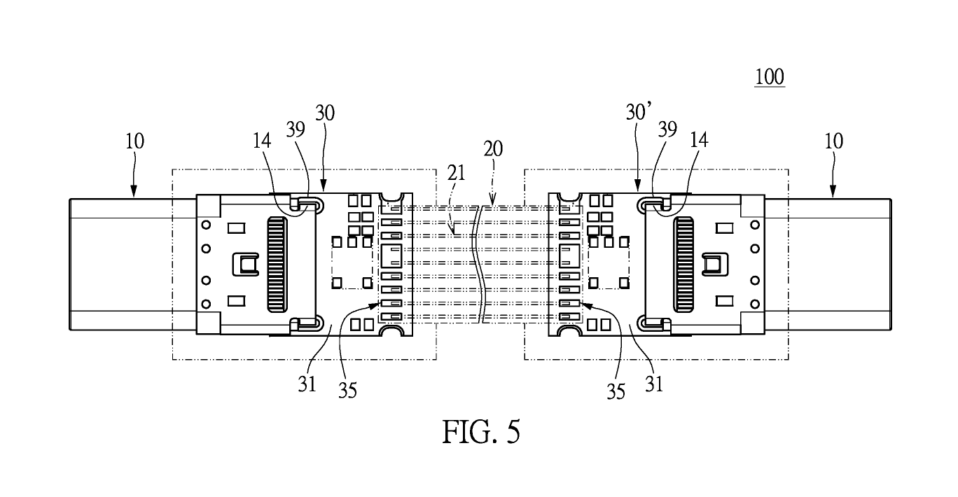

As shown in FIG. 5, in the same manner, pin names of the first-group soldering pads 35 of the second paddle card 30′ from up to down in order are Ground, Vconn (Power), CC (Configuration Channel), Vcc, Vcc (plug Configuration detection), SBU2 (Side Band Use), D+, D− (Differential signal pair of USB 2.0), and SBU1 (Side Band Use). In this embodiment, the width of the ground soldering pad 35g is about twofold of the width of general one of the first-group soldering pads 35.

Reference is made to FIG. 3, the first-group soldering pads 35 includes an integrated soldering pad 35v. The integrated soldering pads 35v is consisted of two Vcc pins. The width of the integrated soldering pad 35v is substantially equal to twofold width (2*w) of another one of the first-group soldering pads (for example, CC) adding an interval (d) between two neighbor soldering pads. Thus, the integrated soldering pad 35v has a larger area capable of transmitting a larger current, and further it is convenient to solder with wires.

Reference is made to FIG. 4, the second-group soldering pads 38 correspond with the signal pins of the terminal assembly 12 of the electrical connector 10, which includes two pairs of receiving differential signal pads (RX+, RX−) 36R and two pairs of transmitting differential signal pads (TX+, TX−) 36T. The two pairs of transmitting differential signal pads (TX+, TX−) 36T and the two pairs of receiving differential signal pads (RX+, RX−) 36R are arranged in an alternate manner. The second-group soldering pads 36 are parallel to the grounding strip pad 38, and formed on the second surface 32 with the grounding strip pad 38, so as to be beneficial to the connection of grounding and shielding.

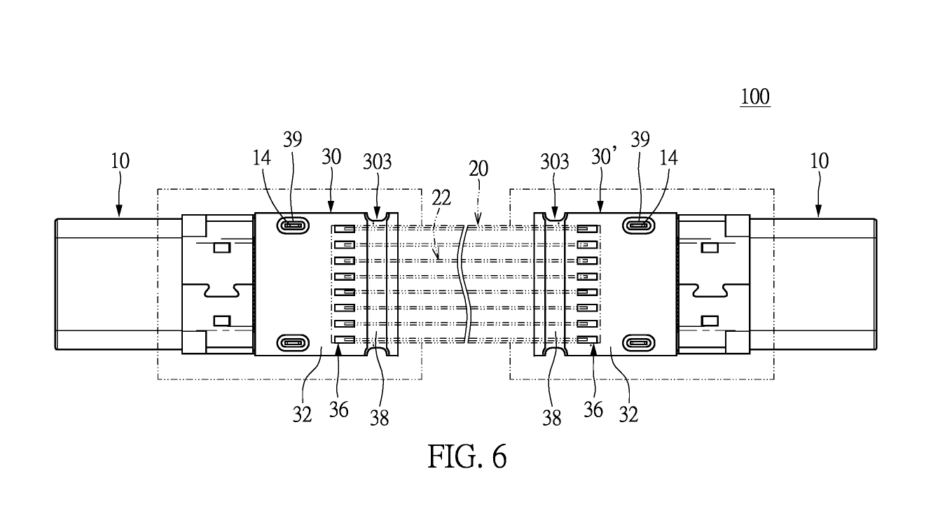

Reference is made to FIG. 6, in a similar manner, pin functions of the second-group soldering pads 36 of the second paddle card 30′ from top to bottom in order are a pair of receiving differential signal pads (RX+, RX−), a pair of transmitting differential signal pads (TX+, TX−), a pair of receiving differential signal pads (RX+, RX−), and a pair of transmitting differential signal pads (TX+, TX−). In this embodiment, all pins of the second-group soldering pads 36, which are used to transmit signal, are positioned on the same surface, the second surface 32 of the paddle card. In addition, the pairing transmitting differential signal pads and the pairing receiving differential signal pads are arranged in an alternate manner, so that it is beneficial to reduce signal interference.

Reference is made to FIG. 5 and FIG. 6, which are a top view and a bottom view of the connecting cable assembly of the present disclosure. The two sides of the connecting cable assembly have an electrical connector assembly, respectively. The connecting cable assembly includes an electrical connector 10 and a first paddle card 30 and a second paddle card 30′. The cable 20 connects with two electrical connector assemblies. In this embodiment, the electrical connector 10 and one paddle card (30 or 30′) are configured as one electrical connector assembly. The cable 20 has a plurality of wires (21, 22). The wires are configured as a first wire group 21 and a second wire group 22. The first paddle card 30 is soldered to the left electrical connector 10, and the second paddle card 30′ is soldered to the right electrical connector 10. In this embodiment, the electrical connectors 10 of the pair are, but not limited to, the same. The two electrical connectors can be different.

In this embodiment, the electrical connector assembly at the right side is similar to the electrical connector assembly at the left side, and it includes the electrical connector 10 and the second paddle card 30′. The second paddle card 30′ has the first-group soldering pads 35, and the second-group soldering pads 36. The first-group soldering pads 35 are formed on the first surface 31 of the second paddle card 30′. The second-group soldering pads 36 are formed on the second surface 32 of the second paddle card 30′.

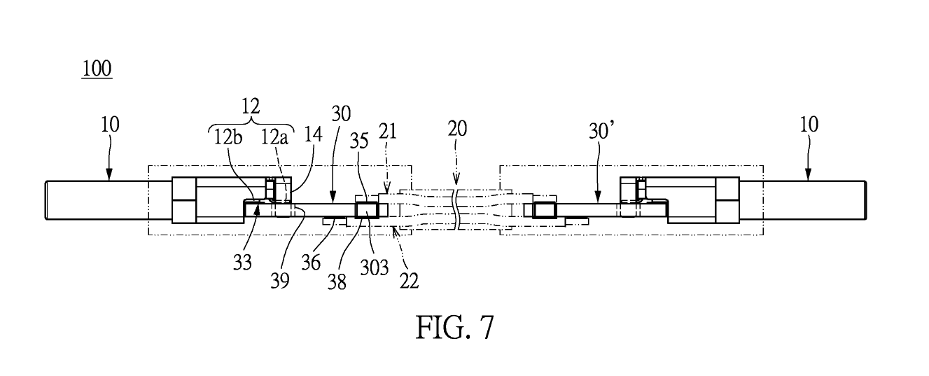

Reference is made to FIG. 7, which is a side view of the connecting cable assembly of the present disclosure. The first wire group 21 has two ends respectively soldered to the first-group soldering pads 35 of the first paddle card 30 and the first-group soldering pads 35 of the second paddle card 30′. The second wire group 22 has two ends respectively soldered to the second-group soldering pads 36 of the first paddle card 30 and the second-group soldering pads 36 of the second paddle card 30′.

One characteristic of the present disclosure is that the circuit layout of the first paddle card 30 is symmetrical to the circuit layout of the second paddle card 30′. To be more specific, the pads of the first paddle card 30 and the second paddle card 30′ and connecting with the cable 20 are symmetrical to each other along a direction perpendicular to the plugging direction of the electrical connector 10, and have a one by one mapping relationships. The pin locations and functions of the first-group soldering pads 35 of the first paddle card 30 are symmetrical to signal pins with positions of the first-group soldering pads 35 of the second paddle card 30′. The pin locations and functions of the second-group soldering pads 36 of the first paddle card 30 are symmetrical to signal pins with positions of the second-group soldering pads 36 of the second paddle card 30′.

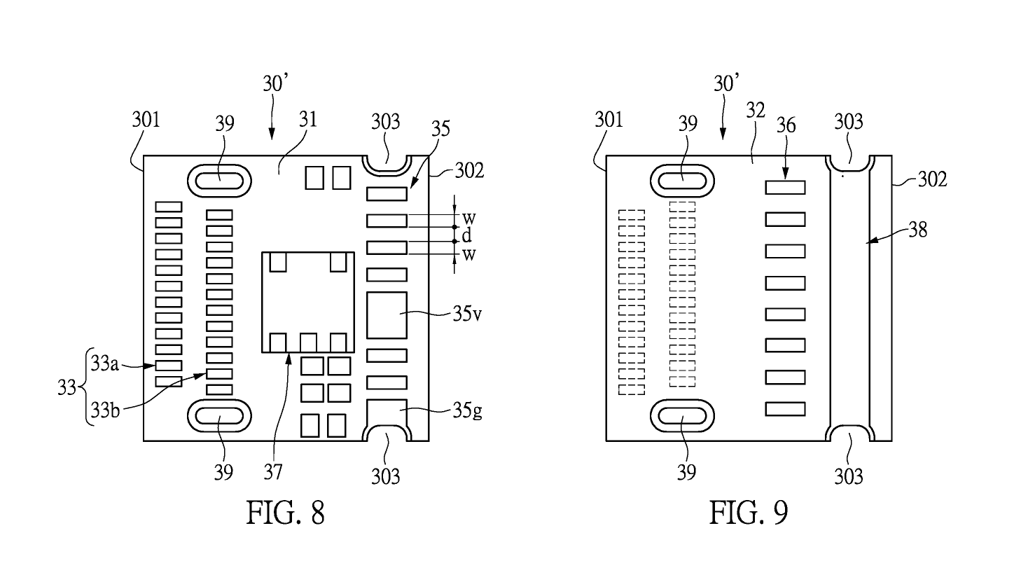

Reference is made to FIG. 7 and FIG. 8, which are a top view and a bottom view of the paddle card of a second embodiment of the present disclosure. The difference between this embodiment and the above embodiment is, the paddle card 30′ has a chip zone 37 formed on the first surface 31, which is a zone that can be connected with an identification chip (not shown), so that an electronic device can identify the connecting cable assembly 100 plugged therein. The two sides of the chip zone 37 can be disposed with resistors (not shown).

The effects of the present disclosure are that the electrical connector assembly and the paddle card can help the electrical connector assembly 10 to be stably assembled with the paddle card 30, and the design of the paddle card 30 helps the electrical connector assembly for conveniently and accurately achieve grounding and shielding.

Since the pin locations and functions of the first-group soldering pads 35 of the first paddle card 30 are symmetrical to the pin locations and functions of the first-group soldering pads 35 of the second paddle card 30′. In addition, the pin locations and functions of the second-group soldering pads 36 of the first paddle card 30 are symmetrical to the pin locations and functions of the second-group soldering pads 36 of the second paddle card 30′. The wires (21, 22) of the cable 20 are arranged according to color and pin functions in the present disclosure, to be distributed in order as the first wire group 21 and the second wire group 22. Due to the symmetrical and mapping relationship, extra time for wire routing can be saved.

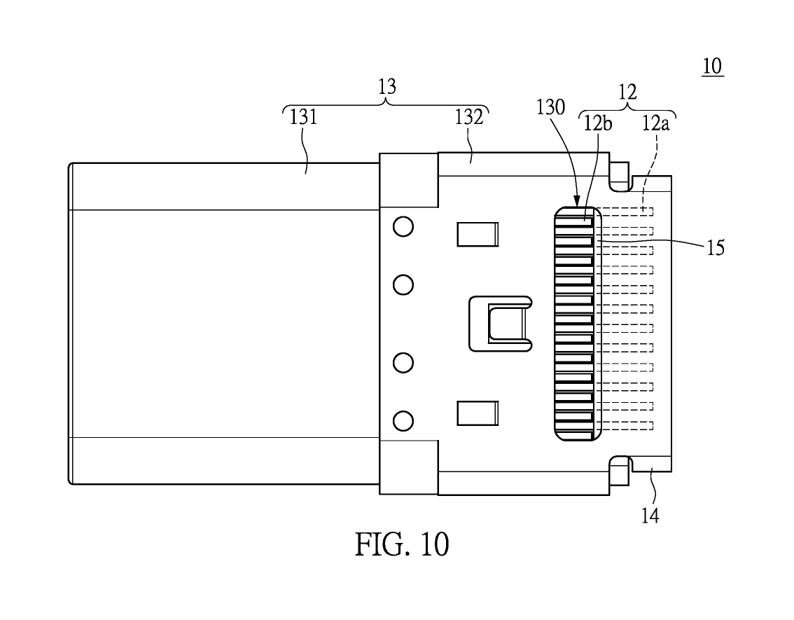

Reference is made to FIG. 10 to FIG. 12. The first embodiment of the present disclosure provides an electrical connector 10. The electrical connector 10 includes a terminal assembly 12, an insulated module 15 and a housing assembly 13. The insulated module 15 supports the terminal assembly 12, and the housing assembly 13 covers the insulated module 15.

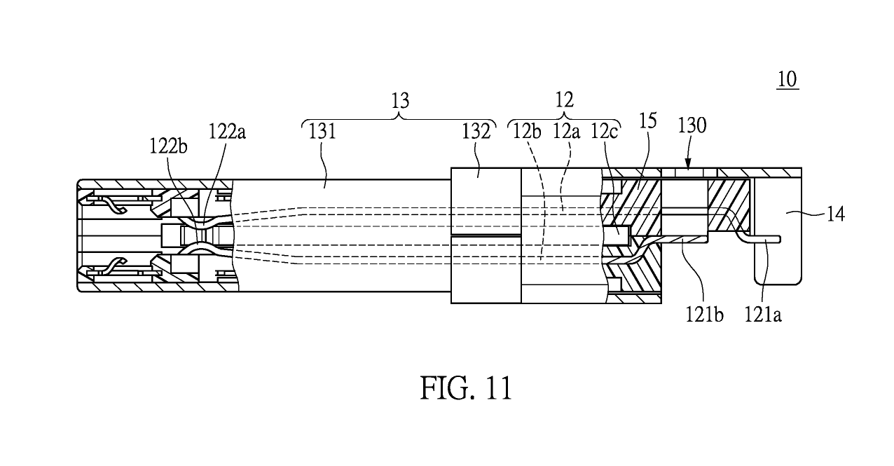

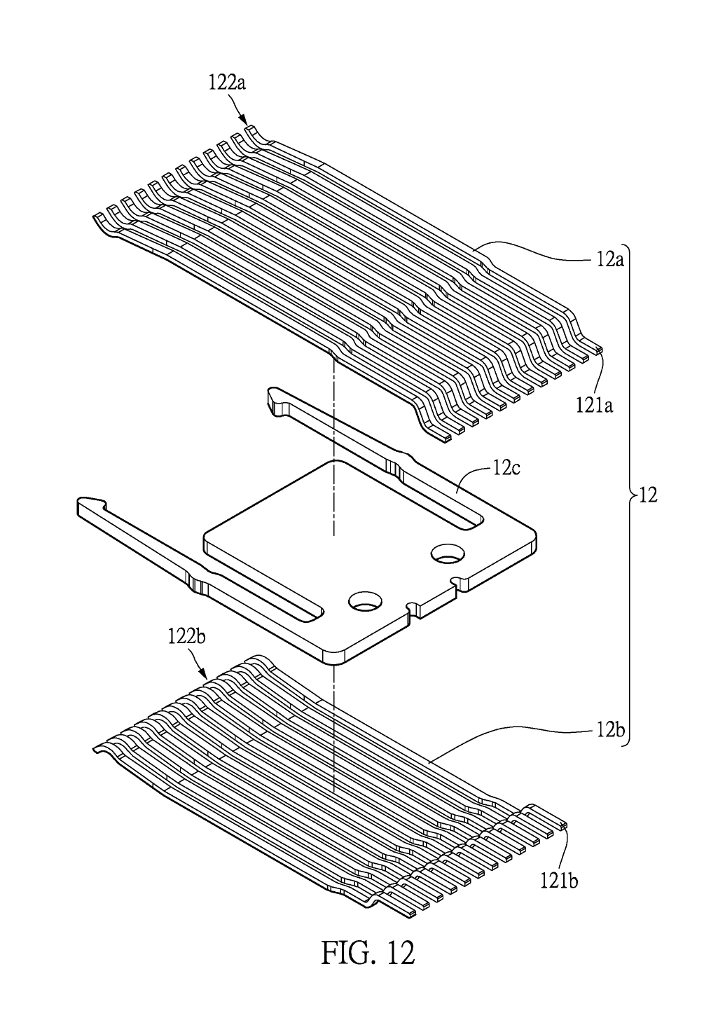

As shown in FIG. 11 and FIG. 12, the terminal assembly 12 includes a soldering part and an electrical connecting part, which are respectively exposed to two opposite sides of the insulated module 15. In this embodiment, the terminal assembly 12 includes a partition 12c, a plurality of first terminals 12a and a plurality of second terminal 12b. From a top view, the first terminals 12a and the second terminals 12b are arranged in an alternate manner in different levels. The partition 12c is disposed between the first terminals 12a and the second terminals 12b, so that the first terminals 12a and the second terminals 12b are separated in different layers.

Reference is made to FIG. 10 and FIG. 11. The insulated module 15 is disposed in the housing assembly 13, to support the terminal assembly 12. The insulated module 15 can be made of isolated plastic material by ejecting or molding. The housing assembly 13 includes a sleeve portion 131 and a shielding portion 132 connected with the sleeve portion 131. The shielding portion 132 correspondingly covers the soldering parts of the terminal assembly 12. The sleeve portion 131 correspondingly covers the electrical connecting part of terminal assembly 12. Further, the housing assembly 13 is formed with at least one inspect window 130. The inspect window 130 is formed on the shielding portion 132 and located correspondingly to the soldering parts of terminal assembly 12, to survey the soldering condition of the soldering parts. This embodiment is illustrated with one inspect window 130 as an example, however, the present disclosure is not limited thereto.

It is worth noting that, concerning the electrical connector 10 of present disclosure, the sleeve portion 131 of the housing assembly 13 can be integrated into one piece to form a seamless sleeve with higher structural strength, so as to increase the supporting characteristic and protective function of the electrical connector 10.

More specifically, as shown in FIG. 10 and FIG. 11, each first terminal 12a has a first soldering portion 121a, and each second terminal 12b has a second soldering portion 121b. The first soldering portion 121a and the second soldering portion 121b are exposed out of the insulated module 15. The first soldering portion 121a of the first terminal 12a and the second soldering portion 121b of the second terminal 12b can be exposed to the inspect window 130. In this embodiment, the inspect window 130 exposes the second soldering portion 121b of the second terminal 12b, as shown in FIG. 10. Further, as shown in FIG. 10 to FIG. 12, parts of the first terminal 12a and parts of the second terminal 12b, which are covered by the insulated module 15, are arranged in an alternate manner in different levels. In contrast, the parts of the first soldering portion 121a and the second soldering portion 121b, which are exposed outside the insulated module 15 under the shielding portion 132, are arranged on the same level in an alternate manner.

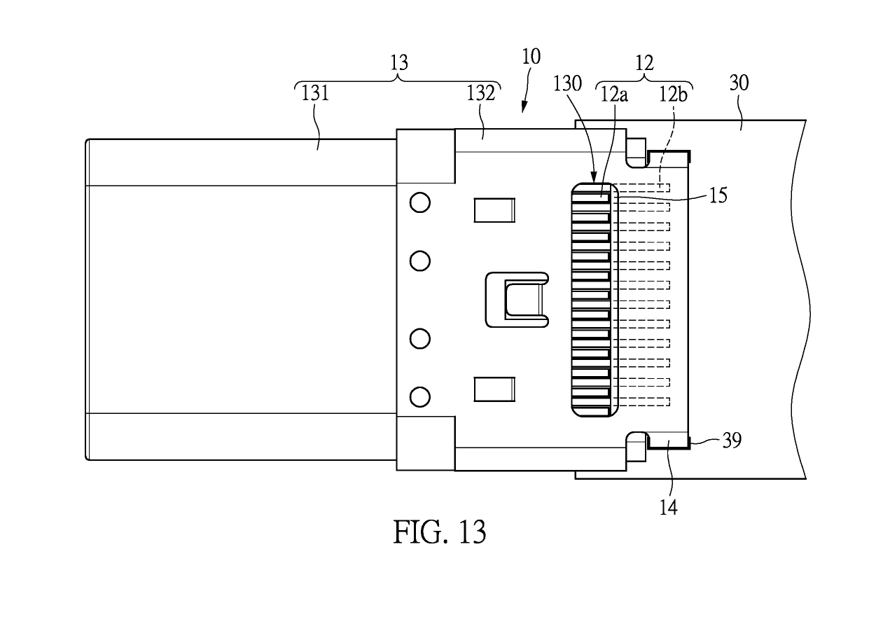

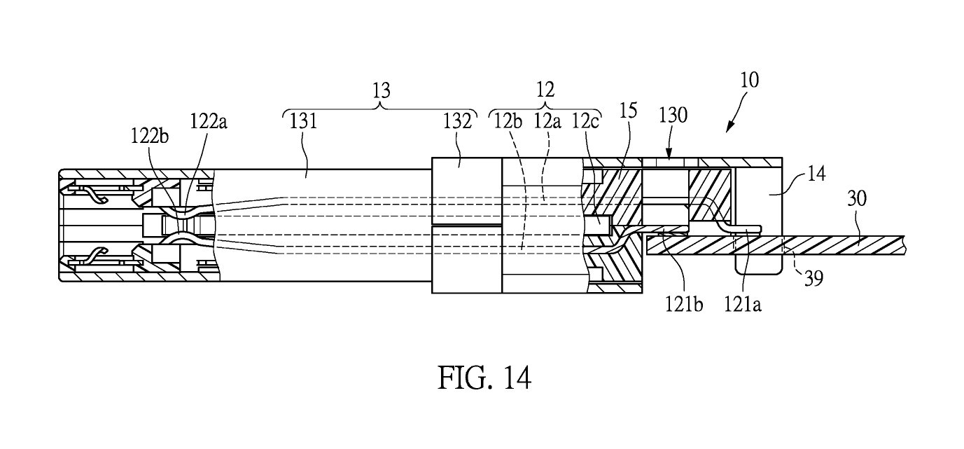

Reference is made to FIG. 13 and FIG. 14, which are perspective views of the electrical connector 10 soldered to the paddle card 30. As mentioned above, the electrical connector 10 includes the terminal assembly 12, the insulated module 15 and the housing assembly 13. The terminal assembly 12 has the soldering part and the electrical connecting part. The detail description can be referred to previous description and is not reiterated herein for the sake of brevity. According to this embodiment, the electrical connector 10 is soldered to the paddle card 30 via the soldering part. The housing assembly 13 has an inspect window 130 for viewing the soldering conditions of the soldering part and the paddle card 30. In this embodiment, the first soldering portion 121a of the first terminal 12a and the second soldering portion 121b of the second terminal 12b are arranged in the same level. In other words, according to this embodiment, the first soldering portion 121a and the second soldering portion 121b are arranged as a front row and a rear row, so that the first soldering portion 121a and the second soldering portion 121b can be soldered on the same surface of the paddle card 30. The first soldering portion 121a, which are exposed out of the insulated module 15, can be observed from a front end of the shielding portion 132 to review the soldering condition of the first soldering portion 121a and the paddle card 30. The second soldering portion 121b can be observed from the inspect window 130, which is formed on the shielding portion 132 of the housing assembly 13, to review the soldering condition.

The electrical connector 10 of the present disclosure further has two fixing legs 14, which are extended vertically from two sides of the shielding portion 132 of the housing assembly 13. In other words, the two fixing legs 14 are extended toward the paddle card 30. The paddle card 30 is formed with a pair of position holes 39 corresponding to positions of the fixing legs 14. When the first soldering portion 121a and the second soldering portion 121b of the electrical connector 10 are disposed on the paddle card 30 for soldering, the fixing legs 14 are inserted into the position holes 39, so as to help to fix the electrical connector 10 being stably connected to the paddle card 30.

The terminal assembly 12 of the electrical connector 10 has soldering parts and electrical connecting parts, the soldering parts and electrical connecting parts are respectively exposed at two opposite outer sides of the insulated module 15. In addition, the housing assembly 13 has at least one inspect window 130, which can used to observe the soldering conditions of the soldering parts and the paddle card 30, so as to review the soldering condition of the electrical connector 10 and the paddle card 30 to increase the soldering yield rate.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. An electrical connector assembly, comprising:
an electrical connector, including a terminal assembly being configured as a plurality of first terminals and a plurality of second terminals, the terminal assembly extending to a rear end of the electrical connector; and
a paddle card, including:
a main body, having a first surface, a second surface, a front edge, and a rear edge, the second surface being opposite to the first surface;
a plurality of contacting pads, disposed on the main body and being close to the front edge; wherein the contacting pads are correspondingly connected to the terminal assembly;
a plurality of first-group soldering pads, disposed on the first surface;
a plurality of second-group soldering pads, disposed on the second surface;
a pair of positioning concaved-portions, respectively formed at two sides of the paddle card and being close to the rear edge; and
a grounding strip pad, formed across the paddle card, the grounding strip pad having two ends respectively extending to a surface of the pair of positioning concaved-portions.

2. The electrical connector assembly as claimed in claim 1, wherein ends of the first terminals and ends of the second terminals are arranged on the same plane, the contacting pads are disposed on the first surface of the paddle card and configured into a plurality of first-row contacting pads and a plurality of second-row contacting pads; wherein the first terminals are connected correspondingly to the first-row contacting pads, and the second terminals are connected correspondingly to the second-row contacting pads.

3. The electrical connector assembly as claimed in claim 2, wherein the first-row contacting pads and the second-row contacting pads are arranged in an alternate manner without alignment.

4. The electrical connector assembly as claimed in claim 3, wherein the paddle card further has a pair of position holes, wherein the electrical connector has a pair of fixing legs respectively inserted in the pair of position holes, wherein the pair of position holes are formed at two sides of the second-row contacting pads.

5. The electrical connector assembly as claimed in claim 1, wherein the grounding strip pad is formed across the second surface of the paddle card along a direction parallel to the rear edge, the grounding strip pad having two ends respectively extending to a surface of the positioning concaved-portions and partially extending to the first surface.

6. The electrical connector assembly as claimed in claim 5, wherein the positioning concaved-portion is U-shaped and is concaved inwardly from a side edge of the paddle card, a width of the grounding strip pad is substantially equal to a maximum width of the positioning concaved-portion.

7. The electrical connector assembly as claimed in claim 6, wherein the first-group soldering pads include a ground soldering pad, and the ground soldering pad is close to one of the positioning concaved-portions and connected to the grounding strip pad.

8. The electrical connector assembly as claimed in claim 7, wherein the first-group soldering pads includes an integrated soldering pad, a width of the integrated soldering pad is equal to twofold the width of one of the other first-group soldering pads adding an interval between two neighbors of the first-group soldering pads.

9. The electrical connector assembly as claimed in claim 8, wherein the second-group soldering pads are corresponded with pin functions of the terminal assembly of the electrical connector, and includes two pairs of transmitting differential signal pads and two pairs of receiving differential signal pads, the two pairs of transmitting differential signal pads and the two pairs of receiving differential signal pads are arranged in an alternate manner and paralleled with the grounding strip pad.

10. A paddle card, comprising:
a main body, having a first surface, a second surface, a front edge, and a rear edge, the second surface being opposite to the first surface;
a plurality of contacting pads, disposed on the main body and being close to the front edge;
a plurality of first-group soldering pads, disposed on the first surface;
a plurality of second-group soldering pads, disposed on the second surface;
a pair of positioning concaved-portions, respectively formed on two sides of the paddle card and being close to the rear edge; and
a grounding strip pad, formed across the paddle card, the grounding strip pad having two ends respectively extended to the pair of positioning concaved-portions.

11. A connecting cable assembly, comprising:
a pair of electrical connectors, respectively having a terminal assembly;
a first paddle card, soldered to one of the pair of electrical connectors, the first paddle card having a first surface, and a second surface; the first paddle card having a plurality of first-group soldering pads, and a plurality of second-group soldering pads, the first-group soldering pads disposed on the first surface of the first paddle card, the second-group soldering pads disposed on the second surface of the first paddle card;
a second paddle card, soldered to the other of the pair of electrical connectors, the second paddle card having a first surface, and a second surface; the second paddle card having a plurality of first-group soldering pads, and a plurality of second-group soldering pads, the first-group soldering pads disposed on the first surface of the second paddle card, the second-group soldering pads disposed on the second surface of the second paddle card;
a cable, having a first wire group and a second wire group, the first wire group having two ends respectively soldered to the first-group soldering pads of the first paddle card and the first-group soldering pads of the second paddle card; the second wire group having two ends respectively soldered to the second-group soldering pads of the first paddle card and the second-group soldering pads of the second paddle card;
wherein pin positions and functions of the first-group soldering pads of the first paddle card are symmetrical to pin positions and functions of the first-group soldering pads of the second paddle card; wherein pin positions and functions of the second-group soldering pads of the first paddle card are symmetrical to pin positions and functions of the second-group soldering pads of the second paddle card.

12. The connecting cable assembly as claimed in claim 11, wherein the terminal assembly of the electrical connector is configured into a plurality of first terminals and a plurality of second terminals, wherein ends of the first terminals and ends of the second terminals are arranged in a coplanar manner; the first paddle card and the second paddle card respectively having a plurality of contacting pads, the contacting pads of the first paddle card disposed on one surface and configured into a plurality of first-row contacting pads and a plurality of second-row contacting pads;
wherein the first terminals are connected correspondingly to the first-row contacting pads, the second terminals are connected correspondingly to the second-row contacting pads.

13. The connecting cable assembly as claimed in claim 12, wherein the first-row contacting pads and the second-row contacting pads are arranged in an alternate manner without alignment.

14. The connecting cable assembly as claimed in claim 13, wherein the first paddle card and the second paddle card respectively have a pair of position holes; wherein the electrical connector has a pair of fixing legs, and the pair of fixing legs are inserted in the pair of position holes; wherein the pair of position holes are formed at two sides of the second-row contacting pads.

15. The connecting cable assembly as claimed in claim 11, wherein the first paddle card and the second paddle card respectively have a pair of positioning concaved-portions, the pair of positioning concaved-portions of the first paddle card formed respectively at two sides thereof, the pair of positioning concaved-portions of the second paddle card formed respectively at two sides thereof.

16. The connecting cable assembly as claimed in claim 15, wherein the first paddle card and the second paddle card respectively have a grounding strip pad, the grounding strip pad is formed across the second surface of the first paddle card along a direction perpendicular to a plugging direction of the electrical connector, the grounding strip pad having two ends respectively extending to a surface of the pair of positioning concaved-portions, and partially extending to the first surface.

17. The connecting cable assembly as claimed in claim 16, wherein the first-group soldering pads of the first paddle card includes a ground soldering pad, the ground soldering pad is close to one of the positioning concaved-portions and connected to the grounding strip pad.

18. The connecting cable assembly as claimed in claim 17, wherein the first-group soldering pads includes an integrated soldering pad, a width of the integrated soldering pad is equal to twofold width of the other first-group soldering pads added an interval between two neighbors of the first-group soldering pads.

19. The connecting cable assembly as claimed in claim 18, wherein the second-group soldering pads are corresponding to pin functions of the terminal assembly of the electrical connector, including two pairs of transmitting differential signal pads and two pairs of receiving differential signal pads, the two pairs of transmitting differential signal pads and the two pairs of receiving differential signal pads are arranged in an alternate manner and paralleled to the grounding strip pad.

20. The connecting cable assembly as claimed in claim 11, wherein the electrical connector includes:
a terminal assembly, having a soldering part;
an insulated module, supporting the terminal assembly; and
a housing assembly, covering the insulated module;
wherein the soldering part is exposed to an outside of the insulated module, and the housing assembly is formed with at least one inspect window to observe the soldering part.
